(19) United States
(12) Patent Application Publication
(10) Pub. No.: US 2013/0299722 A1
(43) Pub. Date: Nov. 14, 2013

(54) ION IMPLANTATION METHOD AND ION IMPLANTER

(71) Applicant: ADVANCED ION BEAM TECHNOLOGY, INC., Hsinchu (TW)

(72) Inventors: CHENG-HUI SHEN, HSINCHU COUNTY (TW); ZHIMIN WAN, SUNNYVALE, CA (US)

(21) Appl. No.: 13/945,013

(22) Filed: Jul. 18, 2013

Related U.S. Application Data
(63) Continuation-in-part of application No. 12/950,366, filed on Nov. 19, 2010, now abandoned.

(51) Int. Cl. H01J 37/317

(52) U.S. Cl. CPC H01J 37/3171
USPC 250/492.3

(57) ABSTRACT

An ion implantation method and an ion implanter with a beam profiler are proposed in this invention. The method comprises setting scan conditions, detecting the ion beam profile, calculating the dose profile according to the detected ion beam profile and scan conditions, determining the displacement for ion implantation and implanting ions on a wafer surface. The ion implanter used the beam profiler to detect the ion beam profile, calculate dose profile and determine the displacement and used the displacement in ion implantation for optimizing, wherein the beam profiler comprises a body with ion channel and detection unit behind the ion channel in the body for beam profile detection. The beam profiler may be a 1-dimensional, 2-dimensional or angle beam profiler.

### REFERENCE TO RELATED APPLICATION

This Application is being filed as a Continuation-in-Part of application Ser. No. 12/950,366, filed 19 Nov. 2010, currently pending.

### BACKGROUND OF THE INVENTION

1. Field of Invention

This invention relates to an ion implantation method, and in particularly, an ion beam profiler is used in the ion implantation method.

2. Background of the Related Art

As shown in FIG. 1, an ion implanter uses a filament 100 to ionize the atoms and/or atom clusters to form ions and/or ion clusters in source chamber 200. An electric field accelerates the ions/ion clusters to form an ion beam 610 and then the ion beam 610 is lead into the channel 300. After passing a mass spectrometer 400, the ions/ion clusters of the ion beam 610 are filtered to have a specific charge-mass ratio. Finally, the ion beam 610 injects into the implantation chamber 500 and bombards onto the surface of a wafer 520. A target base 510 are configured in the implantation chamber 500 for supporting the wafer 520, and a Faraday cup 600 is coupled with the implantation chamber 500 for detecting the beam current. The beam current can be read by an ion beam current detector 700, such as an ampere meter.

Referring to FIG. 2A, the ion beam continuously bombards on the wafer to form an implant line, which the trajectory of the center of the ion beam on the wafer surface. The ion beam is controlled by the focused lens (magnetic field) or the wafer is moved by the target base to make the ion beam scan forward, shift with an distance, scan backward, shift with the distance, scan forward . . . on the wafer to form a plurality of parallel implant lines on the surface of the wafer. When the scan is done over the wafer surface, the wafer is rotated with an angle and the scan operation on the wafer surface is repeated. The rotation angle may be 90°, 60° or 45° . . . , that are respectively called quad, sexton, octal . . . mode scan. The shift distance is called a pitch and the pitch, denoted S, is equal to the distance between two adjacent implant lines, and one scan operation is called one implant that forms a group of parallel implant lines. The scan direction and the shifting direction are respectively defined as x-direction and y-direction. When the scan path, refer to FIG. 2B, does not pass the center of the wafer surface, the formed implant line does not pass the center also. The distance between the center and the scan line is called a displacement, denoted δ (.delta.). The displacement is equal to the distance between the center of the wafer surface and the implant line nearest to the center.

In regardless of the implant mode, it is most import that the group with 0° and the group with 180° of implant lines are parallel, and these two groups of implant lines notably affect the dose uniformity. A pitch shift Δ (.DELTA.) is introduced here, which is the shift distance of the wafer when the wafer is rotated and the next implant begins. The pitch shift Δ is used to avoid the dose to be non-uniform. Under specific scan conditions, the dose uniformity can be enhanced by controlling pitch shift Δ and displacement δ.

For better understanding, the quad implant mode is assumed in the following discussion. FIG. 3A sketches the implant lines with δ=S/2 and without pitch shift (Δ=0), and FIG. 4A sketches the implant lines with δ=S/2 and Δ=S/2. In the condition of δ=S/2, the dose uniformity with Δ=S/2 is better than that with Δ=0, respectively shown as FIG. 4B and FIG. 3B, because the implant lines with 0° and 180° rotation angles are overlapped in case of Δ=0. In condition of δ=S/4. FIG. 5A and FIG. 6A sketches the implant lines with Δ=0 and Δ=S/2. The dose uniformity with Δ=0 is better than that with Δ=S/2, respectively shown as FIG. 5B and FIG. 6B, because the implant lines with 0° and 180° rotation angles are overlapped in case of Δ=S/2.

The above analysis is based on an assumption that the ion beam profile is an ideal Gaussian distribution as shown in FIG. 7A, the centroid of an implant line is at the center of the ion beam with a fixed spreading in y-direction, the spreading is symmetrical to centroid and the implant line is a straight line. In figures, the distance between the centroid and ion beam is noted CT (centroid) and the spreading be SP (spreading). Unfortunately, the real ion beam profile is not an ideal Gaussian distribution as shown FIG. 7B. The centroid does not coincide with the ion beam center, the spreading is not symmetrical to the centroid and the implant lines are not straight and the above conditions lower the implant quality and dose uniformity.

A scan approach for maximizing dose uniformity has been illustrated in lines 19-32, column 8, and FIG. 4 in U.S. Pat. No. 6,908,836 to Murrell et al., wherein the scan lines drawn during each pass are preferably arranged to interleave scan lines of the previous pass to produce a composite raster with a reduced line pitch. In detail, he exemplarily illustrated that the total implantation can be separated into four passes as illustrated in FIG. 4, so as to increase the dose uniformity by reducing an actual line pitch to T/4 if the line pitch of each of the four passes is assumed to be T. However, the scan approach disclosed by Murrell et al. is insufficient for the case that the wafer is rotated before the next implant begins by using the real ion beam as shown FIG. 7B since he failed to consider the reversal of the real ion beam.

FIG. 12A compares a first implant with a second implant by using an ion beam with a centroid biased from an ion beam center, wherein the wafer is rotated between the first implant and the second implant. FIG. 12B sketches the dose distribution of FIG. 12A. In another word, referring to FIG. 12A first, after the wafer is rotated 180° relative to the real ion beam, the centroid CT₁ biased upward from the implant line L1 is reversed to the centroid CT₂ biased downward from the implant line L2, so that the implantation result obtained by averagely arranged the implant lines of all passes as disclosed by Murrell et al. (i.e. Δ=S/2) may be undesired as shown in FIG. 12B. As a result, Murrell et al. is insufficient for such a case since it is difficult to control the real ion beam profile (non-symmetrical distribution) to form an ideal ion beam profile (ideal Gaussian distribution).

The inventor of this invention proposes a new method to improve the dose uniformity, which is illustrated and explained as follows.

### SUMMARY OF THE INVENTION

According to an aspect of this invention, an ion implantation method is proposed. The method comprises detecting the ion beam profile, calculating the dose profile according to the detected ion beam profile, determining the displacement of the ion beam and implanting.

According to an aspect of this invention, the determined displacement can be used in the whole ion implantation, i.e. all rotation angles.

According to an aspect of this invention, the determined displacement can be only used in one implant, i.e. the displacement is used in a rotation angle, and the displacement will be re-determined for next rotation.

According to an aspect of this invention, the beam profile comprises beam position, beam density and beam shape.

According to an aspect of this invention, a beam profiler is used to detect the ion beam profile, calculate the dose profile and determine the displacement. The ion beam profiler may be a 1-dimensional, 2-dimensional or angle beam profiler.

### BRIEF DESCRIPTION OF THE DRAWINGS

FIG. 1 shows an ion implanter.

FIGS. 2A and 2B sketches ion implant lines, the pitch and displacement.

FIGS. 3A, 4A, 5A and 6A sketches the implant lines.

FIGS. 3B, 4B, 5B and 6B sketches the dose uniformity, implant centroid and spreading of FIGS. 3A, 4A, 5A and 6A, respectively.

FIGS. 7A and 7B sketches the beam centroid and spreading of the ideal and real ion beams.

FIG. 8 shows the flow chart of implantation method of this invention.

FIG. 9 sketches a beam profiler of this invention.

FIGS. 10A, 10B and 10C respectively show the ion beam profile in 3-dimensional system(x-y-dose profile), and deviation and the spreading of the ion beam in x- and y-direction in 2-dimensional system (x-dose, y-dose).

FIG. 11 shows an ion implanter with an ion beam profiler.

FIG. 12A compares a first implant with a second implant by using an ion beam with a centroid biased from an ion beam center, wherein the wafer is rotated between the first implant and the second implant.

FIG. 12B sketches the dose distribution of FIG. 12A.

### DETAILED DESCRIPTION OF THE INVENTION

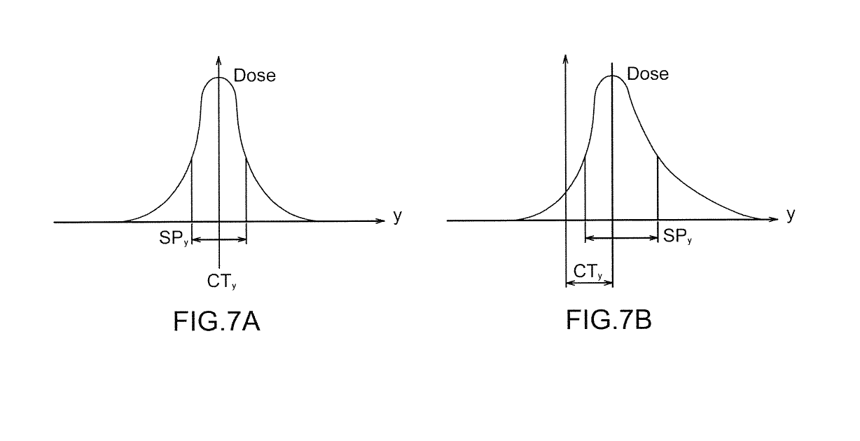

In bi-, quad-, sexton-, octa- . . . mode ion implantation (implant mode), the displacement δ of an ion beam and pitch shift Δ are used to improve dose uniformity. In general, Δ=S/n; and δ is determined according to calculation, where S is a pitch, the distance between two adjacent implant lines in a single implant if the ion beam profile is an ideal Gaussian distribution as shown in FIG. 7A, S is a positive integer, and n is determined according to the implant mode, for example, n=2, 4, 6, 8 . . . in bi-, quad-, sexton-, octa- . . . mode respectively. In a word, the ideal Gaussian distribution represents the centroid of the ion beam is precisely positioned at the center of the ion beam.

Unfortunately, the real ion beam distribution is usually not an ideal Gaussian distribution as shown in FIG. 7B, wherein the centroid of the ion beam is not precisely at the center of ion beam and the spreading is usually not symmetrical to the centroid. Herein, the beam information includes beam position, beam intensity and beam shape, and is defined as an ion beam profile. Further, the real ion beam shape can not be completely controlled, the centroid of the real ion beam may be biased and the real ion beam intensity is not symmetrical to the ion beam center, and those uncontrollable factors distort the ideal assumption and lower the dose uniformity. The inventor, in this invention, proposes a new skill to optimize the dose uniformity by dynamically adjusting the displacement δ (.delta.) according to the beam profile.

Dose is predetermined, which is measured by ion (atom) numbers per unit area (ions/cm²), and the scan conditions are also predetermined. The scan velocity, the moving velocity of the ion beam on the scan path, can be controlled to reach the predetermined dose. One scan is defined to be a forward or backward scan, and a forward scan and a backward scan form two parallel implant lines, and one implant includes a plurality of times scan to be over the wafer surface to form a group of parallel, and one whole implantation is defined to finish a wafer implantation. After one implant is finished, the ion beam or the wafer is rotated and shifted, and then the next implant is preceded, and the superposition of these implant lines forms a dose profile. As a result, different dose profiles can be calculated according to different simulated implantations simulated with different displacements δ by using an ion beam profile in a computing device, such as a computer, or either on different wafers or on different portions on a wafer, and the dose uniformities are determined by the dose profiles, wherein the displacement δ is equal to a distance between a center of a wafer and the nearest implant line. Therefore, an optimized dose profile and an optimized dose uniformity can be obtained as long as an optimized displacement δ is determined according to the calculation.

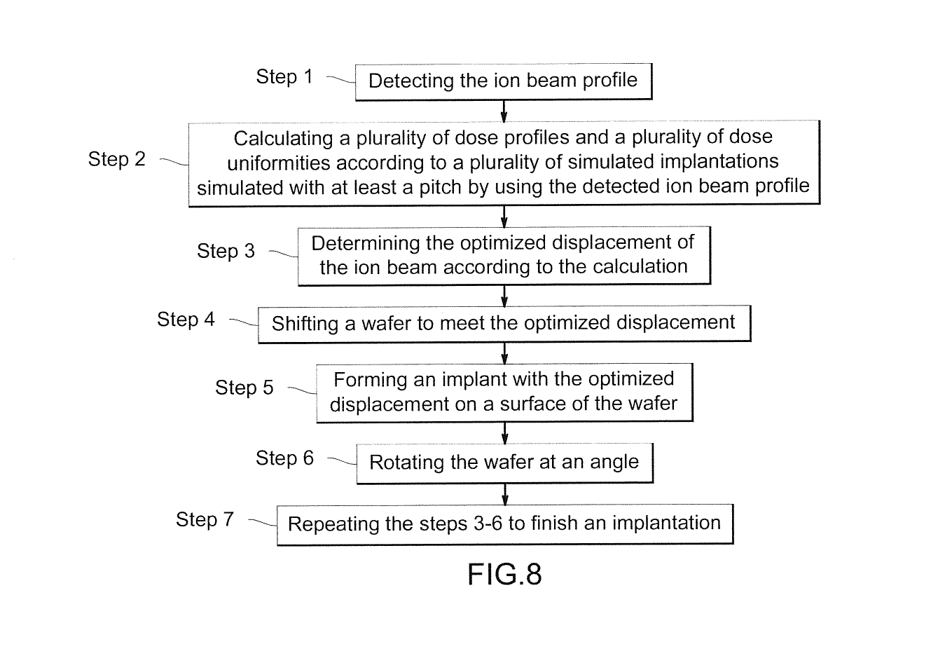

According to an aspect of this invention, an ion implantation method is proposed shown as FIG. 8, and the method comprises:
Step 1: detecting the ion beam profile,
Step 2: calculating a plurality of dose profiles and a plurality of dose uniformities according to a plurality of simulated implantations simulated by using the detected ion beam profile,
step 3: determining the optimized displacement δ of the ion beam according to the calculation,
Step 4: shifting a wafer to meet the optimized displacement,
Step 5: forming an implant with the optimized displacement on a surface of the wafer,
Step 6: rotating the wafer at an angle, and
Step 7: repeating the steps 3-6 to finish an implantation.

In step 1, an ion beam profile is detected before implanting. The ion beam may scan a beam profiler first, and the beam profiler detects and measures the ion beam. The ion beam profiler can be 1-dimensional (y-directional) or 2-dimensional (x- and y-directional) beam profiler for detecting the ion distribution in y-directional distribution or x-y-planar distribution. When ions bombard on the detector of the ion beam profiler to be detected, the ion distribution on the detector is similar with or the same as the ion beam distribution on the wafer surface.

In step 2, under the predetermined scan conditions, the detected beam profile is used to simulate m simulated implantations with m displacements δ and at least a pitch on a simulated wafer, so as to calculate m dose profiles and m dose uniformities accordingly. In detail, each one of the simulated implantations can have n simulated implants with n orientations averagely arranged around 360°, and thus each simulated implant can be denoted as I(m,n). Further, the nth simulated implant at mth displacement δ I(m,n) can have a plurality of nth simulated implant lines (denoted as L(m,n) hereinafter) perpendicular to the nth orientation (denoted as O(m,n) hereinafter) and a mth displacement (denoted as δ(m,n) hereinafter) equal to a distance between a center of a surface of the simulated wafer and the one of the simulated implant lines L(m,n) nearest to the center, wherein both of m and n are positive integers. Moreover, the pitch is equal to a distance between adjacent two of the simulated implant lines L(m,n). Accordingly, different displacements δ(m,n) are corresponding to different dose profiles and different dose uniformities, and all of the calculated dose profiles and dose uniformities will be similar to or the same as the dose profiles and dose uniformities actually formed on a wafer surface.

In order to provide a thorough understanding of the present invention, Table 1 exemplarily lists a specific example comprising 8 simulated implantations (i.e. m=1-8) simulated in a quad-implant mode (i.e. n=1-4), so as to result 32 simulated implants as listed below. In such a case, all of the 8 simulated implantations are simulated with the same pitch (denoted as “S” herein), for example 15 mm, and the 8 simulated implants corresponding to the same orientation are simulated with 8 different displacements δ averagely divide the pitch S, such as S/8 to S in Table 1, and the 4 displacements δ corresponding to the same group of orientation (for example 0°, 90°, 180° or 270°) in different simulated implantations are equal. However, in other non-illustrated embodiments, it is possible to generate more simulated implantations simulated with other pitches, for example, simulating 8 simulated implantations with a pitch equal to 20 mm, 8 simulated implantations with a pitch equal to 25 mm and 8 simulated implantations with a pitch equal to 30 mm. Besides, in other non-illustrated embodiments, the 8 displacements δ in the same simulated implantations (i.e. m is a constant and n is a variable) can randomly divide the pitch, but the 4 displacements δ corresponding to the same orientation in different simulated implantations (i.e. m is a variable and n is a constant) are still equal. As the listing in the Table 1, the 8 different dose profiles and dose uniformities referring to 8 different displacements δ for each of the 4 orientations can be calculated.

TABLE 1

| | δ | | | | | | | |
|---|---|---|---|---|---|---|---|---|
| Orientation | S/8 | 2S/8 | 3S/8 | 4S/8 | 5S/8 | 6S/8 | 7S/8 | S |
| 0° | I11 | I21 | I31 | I41 | I51 | I61 | I71 | I81 |
| 90° | I12 | I22 | I32 | I42 | I52 | I62 | I72 | I82 |
| 180° | I13 | I23 | I33 | I43 | I53 | I63 | I73 | I83 |
| 270° | I14 | I24 | I34 | I44 | I54 | I64 | I74 | I84 |

In step 3, the first optimized displacement δ₁ corresponding to the orientation 0° can be determined by selecting the best dose profile and dose uniformity from the dose profiles and dose uniformities calculated from the simulated implants 111 to 181. In another word, since different displacements δ correspond to different dose profiles and dose uniformities, the first optimized displacement δ₁ correspond to the best dose profile and dose uniformity.

In step 4, a wafer is shifted to meet the first optimized displacement δ₁.

In step 5, a first implant with the first optimized displacement δ₁ is formed on a surface of the wafer.

In step 6, the wafer is further rotated to the next orientation, for example, 90°, 180° or 270° for the next implant.

Thereafter, the steps 3-6 are repeated for the second implant, the third implant and the fourth implant respectively corresponding to the other three orientations 90°, 180° and 270°, so as to finish an optimized implantation. In another word, all of the four implants are proceeded by using the four optimized displacements δ_{M}, all of the four optimized displacements δ_{M} correspond to all of the best calculated dose profiles and dose uniformities corresponding to the four different orientations, and all of the best calculated dose profiles and dose uniformities are similar to or the same as the dose profiles and dose uniformities on a wafer surface. As a result, the dose profile and dose uniformity on the wafer surface is the best.

It should be noted that although it is possible to generate a significant number of simulated implants I(m,n) for determining the optimized displacement, the inventor finds that the optimized displacement is usually, not always, resulted in a case that the wafer is always rotated along a clockwise direction or a counterclockwise direction in the step 6 and always shifted close to or away from the center of the wafer with the same pitch shift (Δ) in the step 4. In a word, the optimized simulated implantation is probably resulted from the combination of the simulated implants 111, 132, 153 and 174, the combination of the simulated implants 121, 142, 163 and 184, the combination of the simulated implants 131, 152, 173 and 114, the combination of the simulated implants 141, 162, 183 and 124, the combination of the simulated implants 151, 172, 113 and 164, the combination of the simulated implants 161, 182, 123 and 144, the combination of the simulated implants 171, 112, 133 and 154, the combination of the simulated implants 181, 122, 143 and 154, and vice versa. As a result, in a quad-implant mode, it is possible to obtain an optimized implantation by proceeding a first implant with a displacement δ₁ equal to x mm at y°, a second implant with a displacement δ₂ equal to x+2*(S/8) mm at (y+90)°, a third implant with a displacement δ₃ equal to x+4*(S/8) mm at (y+180)° and a four implant with a displacement δ₄ equal to x+6*(S/8) mm at (y+270)°, wherein x represents an initial displacement and ranges between 0 mm and 2*(S/8) mm, while the y represents an initial orientation and ranges between 0° mm and 90°. Based upon the observation, it is possible to further reduce the total number of the simulated implants significantly. The details about applying the present invention in a bi-implant mode, a sexton-implant mode, an octa-implant mode . . . and so on are substantially the same as the embodiment illustrated above and thus omitted herein.

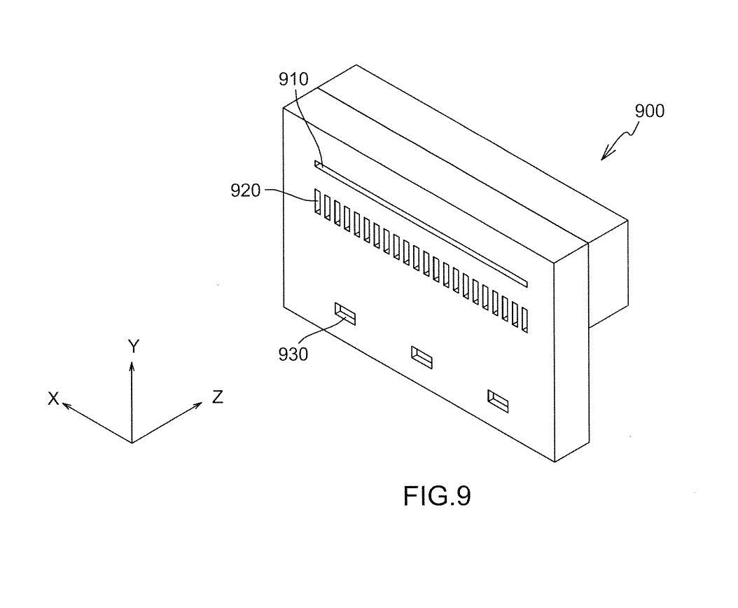

Continuously, the inventor provides the embodiments of a 1-dimensional, 2-dimensional and angle ion beam profiler. It is noted that the embodiments is used to illustrate this invention not to limit the scope of the invention. Refer to FIG. 9, the profiler 900 integrates three kinds of ion beam profiler for convenience to explain the ion beam profilers, but however these ion beam profilers can be separated and used alone or like this drawing multiple beam profilers are integrated together. The ion beam profiler comprises a body with at least one channel arranged in a special pattern and at least one detection unit (not shown) behind the channel. For example, the channel is configured as a slot or a set of arranged holes.

For example, 1-dimensional beam profiler 910 comprises a channel, which is configured as a slot, and the detection unit behind the slot, shown at the upper of FIG. 9. The ion beam scans the 1-dimensional beam profiler 910, which is configured to be bar slot along x-direction, from top to bottom(y-direction), and the ion beam profile is detected by the detection unit when the ions pass the slot, and a y-directional beam profile is obtained. The y-directional beam profile is detected and then the corresponding y-directional dose profile can be calculated and the dose uniformity can be found

For example, 2-dimensional beam profiler 920 comprises a channel, which is configured as an array or a matrix of holes, and detection unit behind these holes, shown at the middle of the FIG. 9. The ion beam passes the holes and sensed by the detection unit to form a 2-dimensional contour map of the ion beam. The 2-dimensional contour map is corresponding to x-y-planar beam profile, and the dose profile can be calculated by the beam profile, and finally, the dose uniformity can be determined.

For example, the angle beam profiler comprises a channel, which is configured as a row of three holes 930, and a detection unit behind the holes, shown at the lower of FIG. 9. The ion beam passes these holes to the detection unit and the beam angle profile can be detected. The beam centroid and the spreading can be obtained by the beam angle profile, so the dose profile can be calculated by the centroid and the spreading of the beam angle profile, and the best displacement is found also.

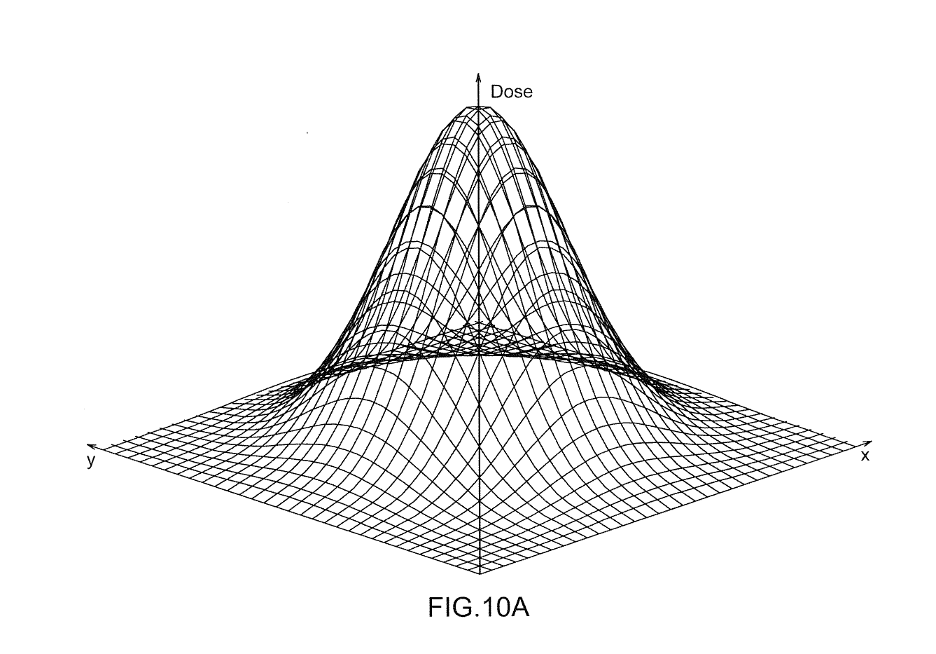

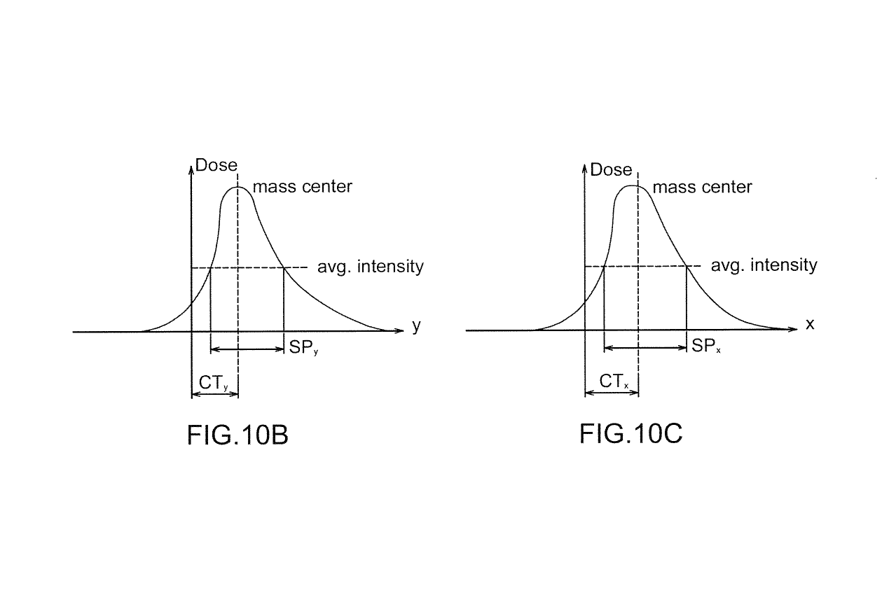

The I-dimensional and the 2-dimensional can be integrated to figure out beam shape, and the beam shape can be shown as a 3-dimensional beam profile, x-y-dose profile shown as FIG. 10A. FIG. 10B and FIG. 10C respectively show the deviation of the beam centroid and the spreading width in x- and y-direction. Once the beam profile is obtained, the beam profile can be calculated to easily determine the optimized displacement δ_{M}.

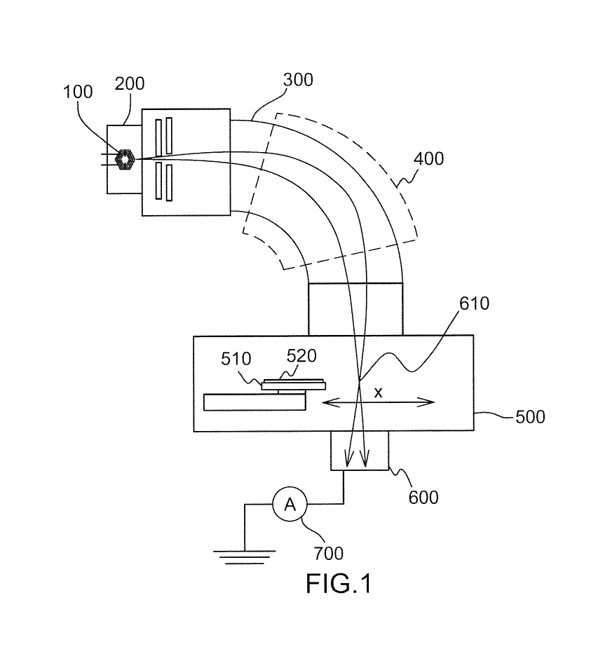

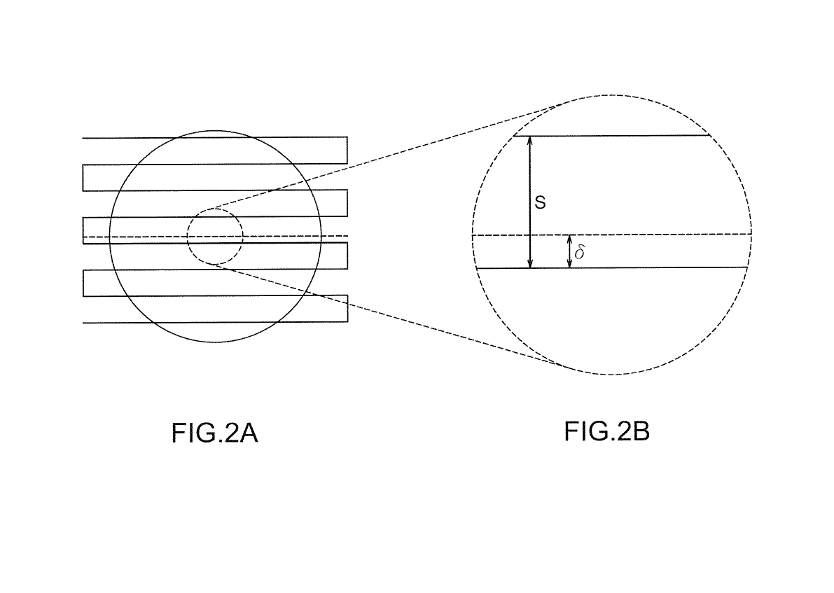

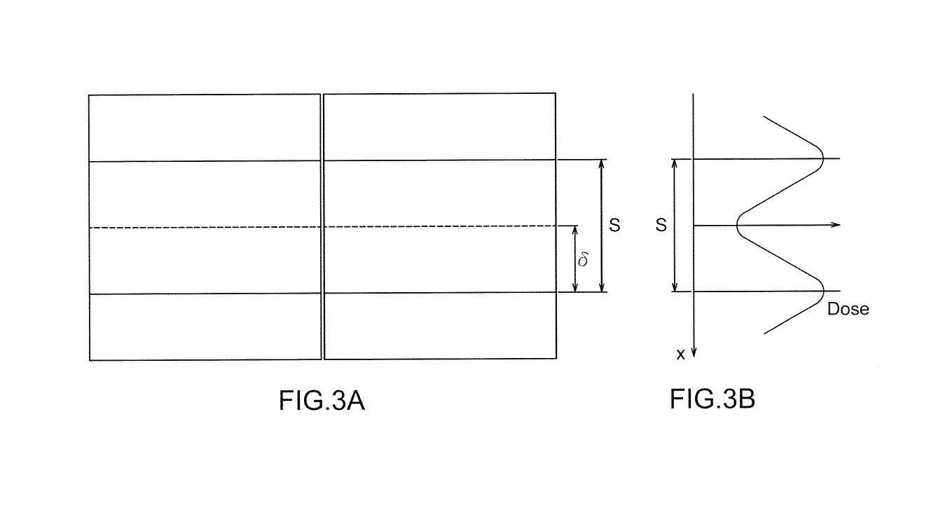

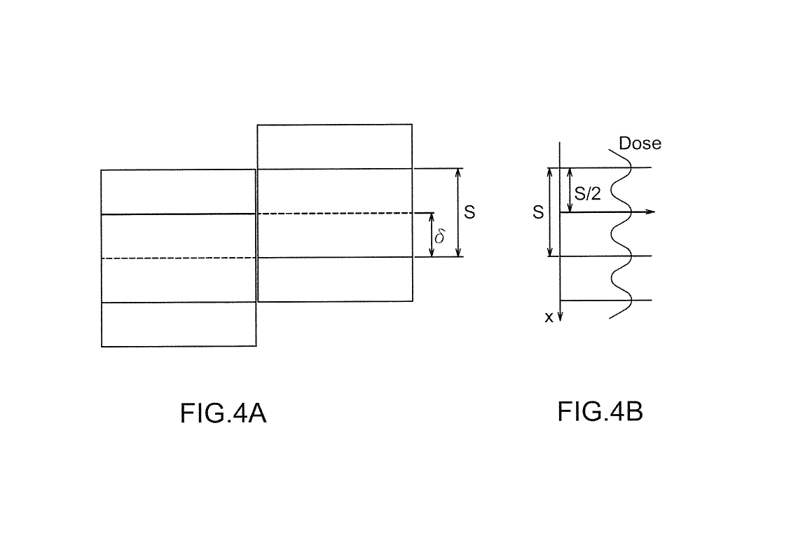

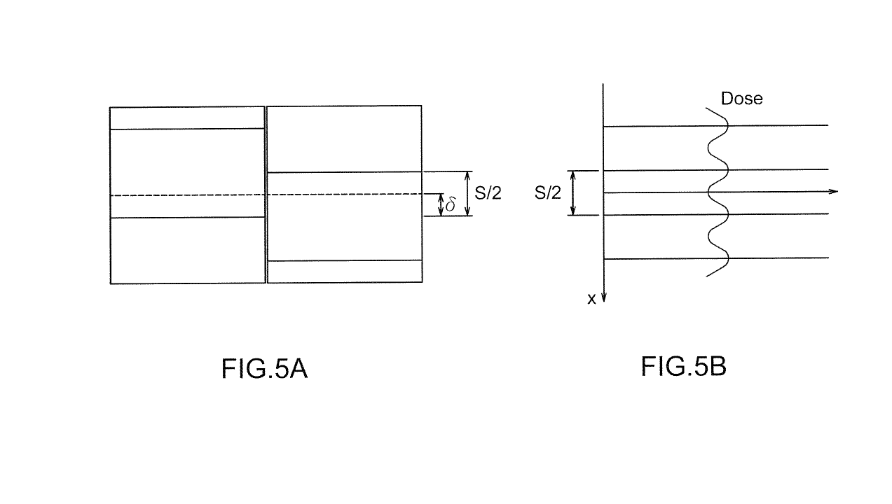

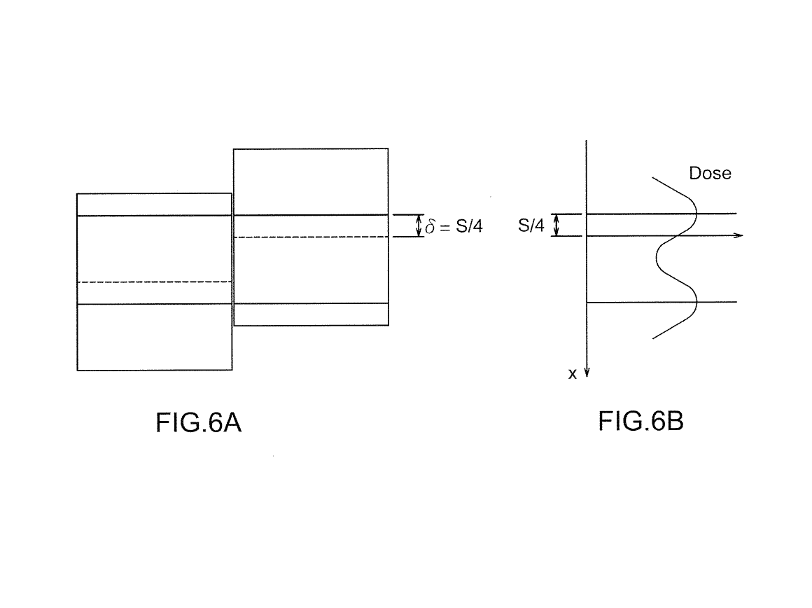

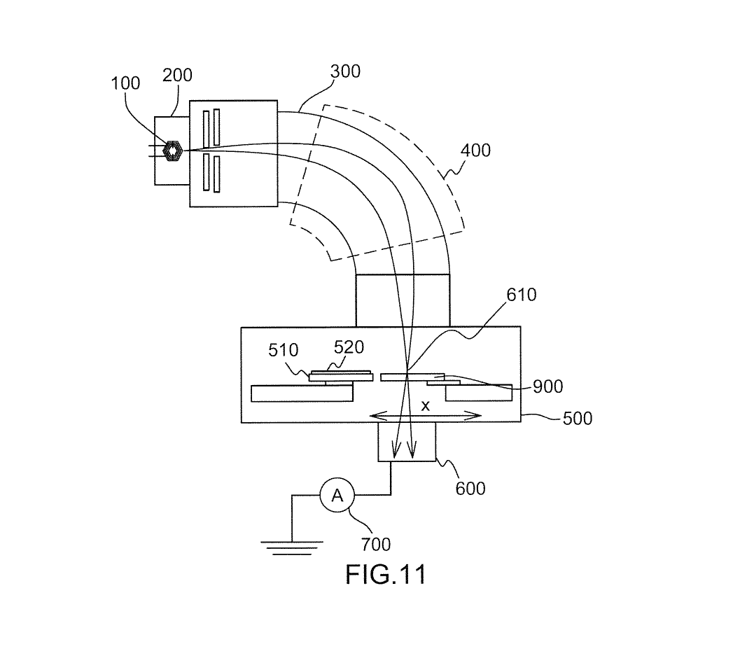

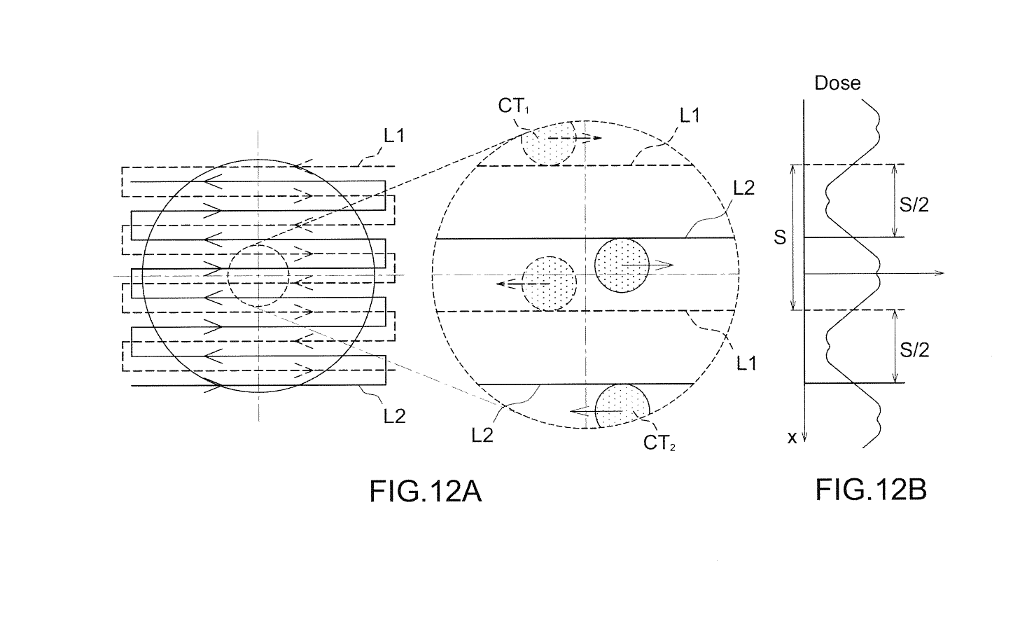

FIG. 11 shows an embodiment of an implanter, which comprises an ion beam profiler 900. The ion beam profiler can detect the beam profile and calculate the dose profile and dose uniformity. Therefore, the ion beam profiler can be positioned at the position of the wafer to get the most real dose profile, and of course, the beam profiler can be put another position. The other elements of the ion implanter and the configuration are similar with that shown in FIG. 1.

Although this invention has been explained in relation to its preferred embodiment, it is to be understood that modifications and variation can be made without departing the spirit and scope of the invention as claimed.

What is claimed is:

1. An ion implantation method comprising:
a. detecting an ion beam profile;
b. calculating a plurality of dose profiles and a plurality of dose uniformities according to a plurality of simulated implantations simulated with at least a pitch on a simulated wafer by using the ion beam profile, wherein each one of the simulated implantations has n simulated implants with n orientations averagely arranged around 360°, the nth simulated implant has a plurality of nth simulated implant lines perpendicular to the nth orientation and a nth displacement equal to a distance between a center of a surface of the simulated wafer and the one of the nth simulated implant lines nearest to the center, and n is a positive integer;
c. determining a nth optimized displacement from all of the nth displacements of all of the simulated implantations according to the calculation;
d. shifting a wafer to meet the nth optimized displacement;
e. forming a nth implant with the nth optimized displacement on a surface of the wafer;
f. rotating the wafer at an 360/n angle; and
g. repeating the steps (c) to (f) n−1 times to finish an implantation.

2. The ion implantation method according to claim 1, wherein a beam profiler is used in detecting step.

3. The ion implantation method according to claim 2, wherein the beam profiler is a 1-dimensional beam profiler for detecting one dimensional beam profile.

4. The ion implantation method according to claim 3, wherein the 1-dimensional beam profiler comprises a body with a slot and a detection unit behind the slot in the body.

5. The ion implantation method according to claim 2, wherein the beam profiler is a 2-dimensional beam profiler for detecting two dimensional beam profile.

6. The ion implantation method according to claim 5, wherein the 2-dimensional beam profiler comprises a body with an array of holes and a detection unit behind the holes in the body.

7. The ion implantation method according to claim 5, wherein the 2-dimensional beam profiler comprises a body with a matrix of holes and a detection unit behind the holes in the body.

8. The ion implantation method according to claim 2, wherein the beam profiler is an angle beam profiler for detecting beam angle profile, which comprises beam centroid and spreading.

9. The ion implantation method according to claim 8, wherein the angle beam profiler comprises a body with a row of three holes and a detection unit behind the holes in the body.

10. The ion implantation method according to claim 1, wherein the angle is 180° in regard to a bi-mode implant.

11. The ion implantation method according to claim 1, wherein the angle is 90° in regard to a quad-mode implant.

12. The ion implantation method according to claim 1, wherein the angle is 60° in regard to a sexton-mode implant.

13. The ion implantation method according to claim 1, wherein the angle is 45° in regard to an octo-mode implant.

14. The ion implantation method according to claim 1, wherein at least some of the simulated implantations are simulated with different pitches than the others.

15. The ion implantation method according to claim 1, wherein a distance that the wafer shifted in the step d is equal to 1/n of the pitch.

16. The ion implantation method according to claim 1, wherein the wafer is always shifted close to a center of the wafer in the step d.

17. The ion implantation method according to claim 1, wherein the wafer is always shifted away from a center of the wafer in the step d.

18. The ion implantation method according to claim 1, wherein the wafer is always rotated along a clockwise direction.

19. The ion implantation method according to claim 1, wherein the wafer is always rotated along a counterclockwise direction.

20. The ion implantation method according to claim 1, wherein the first orientation is at y°, wherein y is an angle value larger than or equal to 0° and smaller than 360°.
